(19) United States
(12) Patent Application Publication
(10) Pub. No.: US 2014/0035069 A1
(43) Pub. Date: Feb. 6, 2014

(54) FIELD EFFECT TRANSISTOR HAVING A TROUGH CHANNEL

(71) Applicant: Avalanche Technology Inc., Fremont, CA (US)

(72) Inventors: Kimihiro Satoh, Beaverton, OR (US); Yiming Huai, Pleasanton, CA (US)

(73) Assignee: Avalanche Technology Inc., Fremont, CA (US)

(21) Appl. No.: 14/043,477

(22) Filed: Oct. 1, 2013

Related U.S. Application Data
(63) Continuation-in-part of application No. 13/136,051, filed on Jul. 21, 2011.
(60) Provisional application No. 61/863,199, filed on Aug. 7, 2013.
(60) Provisional application No. 61/520,119, filed on Jun. 4, 2011.

(51) Int. Cl. H01L 29/78; H01L 29/66

(52) U.S. Cl. CPC H01L 29/78; H01L 29/66477
USPC 257/410; 257/412; 438/270

(57) ABSTRACT

The present invention is directed to a field effect transistor having a trough channel structure. The transistor comprises a semiconductor substrate of a first conductivity type having a trough structure therein with the trough structure extending along a first direction; an insulating layer formed on top of the trough structure; a gate formed on top of the insulator layer in a second direction perpendicular to the first direction and extending over and into the trough structure with a gate dielectric layer interposed therebetween; a source and a drain of a second conductivity type opposite to the first conductivity type formed in the trough structure on opposite sides of the gate.

### CROSS-REFERENCE TO RELATED APPLICATIONS

The present application claims the benefit of the provisional application bearing Ser. No. 61/863,199 filed Aug. 7, 2013 and is a continuation-in-part of the commonly assigned application bearing Ser. No. 13/136,051 filed Jul. 21, 2011, entitled “Trough Channel Transistor and Methods for Making the Same,” which claims the benefit of the provisional application bearing Ser. No. 61/520,119 filed Jun. 4, 2011.

### BACKGROUND

The present invention relates generally to a field effect transistor device, and more particularly, to a field effect transistor device having a trough channel through which electric current flows between source and drain.

Field-Effect Transistors (FETs), particularly Metal-Oxide-Semiconductor Field-Effect Transistors (MOSFETs), are the fundamental building block of integrated circuits and are ubiquitous in modern electronic devices. In a MOSFET device, when a voltage is applied to a gate, charge carriers move between a source and a drain region via a conductive channel, which is formed by an electric field generated by the gate voltage through a thin layer of dielectric material interposed in between the gate and the channel. The channel can be of p-type or n-type conductivity, depending on the substrate and the fabrication method.

For the past half century the number of transistors on integrated circuits has been doubling every two years, following a trend commonly known as Moore's Law. Such a rapid increase in transistors is mainly accomplished by the miniaturization thereof. However, several difficulties can arise when scaling the transistor size, particularly the channel length, to sizes of a few tens of nanometers. As the channel length is reduced, there is a propensity for the formation of parasitic conduction paths between the source and the drain, thereby causing punch through current leakages. Another obstacle encountered in shrinking of transistors is reduced current drivability caused by the reduced width of the current-carrying channel. This can be a significant issue for newly emerged resistive memory devices which require higher current to switch their memory state.

To mitigate the above mentioned problems associated with the miniaturization of conventional transistors, a three dimensional MOSFET having a conductive channel region wrapped around a “fin” shaped silicon has been disclosed, for instance, in U.S. Pat. No. 7,948,037B2 issued to Chen et alia. FIG. 1 is a three dimensional view of such a FinFET device, which includes a substrate 50 comprising a lower substrate base layer 52 and an insulator base layer 54 disposed thereabove, a silicon fin 56 disposed on the insulator base layer 54, and a gate 58 disposed on the insulator base layer 54 and wrapped around the silicon fin 56 with a thin gate dielectric layer 60 interposed therebetween. When an appropriate voltage is applied to the gate 58, a conductive channel through which current flows is formed on the surface region of the fin 56 wrapped by the gate dielectric layer 60. Compared with the conventional planar MOSFET, the FinFET device illustrated in FIG. 1 has higher the current drivability because of the wrap-around channel design thereof.

A problem, however, associated with the FinFET device described above is that the active region of the device is formed on the insulator base layer 54, thereby making the substrate biasing of the FinFET device difficult.

Another problem associated with the FinFET device described above is that the need for insulator base layer 54 necessitates the use of expensive substrates such as Silicon-On-Insulator (SOI), thereby making the FinFET device more costly to fabricate.

For the foregoing reasons, there is a need for a device that can be easily biased and inexpensively manufactured.

### SUMMARY

The present invention is directed to a transistor device that satisfy this need. An device having features of the present invention comprises a semiconductor substrate of a first conductivity type having a trough structure therein with the trough structure extending along a first direction; an insulating layer formed on top of the trough structure; a gate formed on top of the insulator layer in a second direction perpendicular to the first direction and extending over and into the trough structure with a gate dielectric layer interposed therebetween; a source and a drain of a second conductivity type opposite to the first conductivity type formed in the trough structure on opposite sides of the gate.

According to another aspect of the present invention, a method for manufacturing a transistor device having a trough channel comprises the steps of providing a semiconductor substrate having a first type conductivity; depositing an insulating layer on top of the semiconductor substrate; forming a trough structure in the semiconductor substrate; forming a gate dielectric layer on the surface of the trough structure; forming a gate on top of the insulating layer with the gate extending over and into the trough structure with the gate dielectric layer interposed therebetween; and forming a source and a drain having a second conductivity type opposite to the first conductivity type in the trough structure by ion implantation using the gate as a mask.

### BRIEF DESCRIPTION OF THE DRAWINGS

These and other features, aspects, and advantages of the present invention will become better understood with regard to the following description, appended claims, and accompanying drawings where:

FIG. 1 is a perspective view illustrating a prior art FinFET device;

FIG. 2 is a perspective view of an embodiment of the present invention as applied to a MOSFET device having a trough shaped channel through which electric current flows;

FIG. 3 is a perspective view of the device 80 of FIG. 2 with the gate 88 and the insulating layer 86 hidden to illustrate components below and behind the gate 88;

FIGS. 4-8 are perspective views illustrating various stages in formation of a MOSFET device having a trough shaped channel according to some embodiments of the present invention;

FIG. 9 is a perspective view of another embodiment of the present invention as applied to a MOSFET device having a trough shaped channel through which electric current flows; and

FIGS. 10-15 are perspective views illustrating various stages in formation of a MOSFET device having a trough shaped channel according to some embodiments of the present invention.

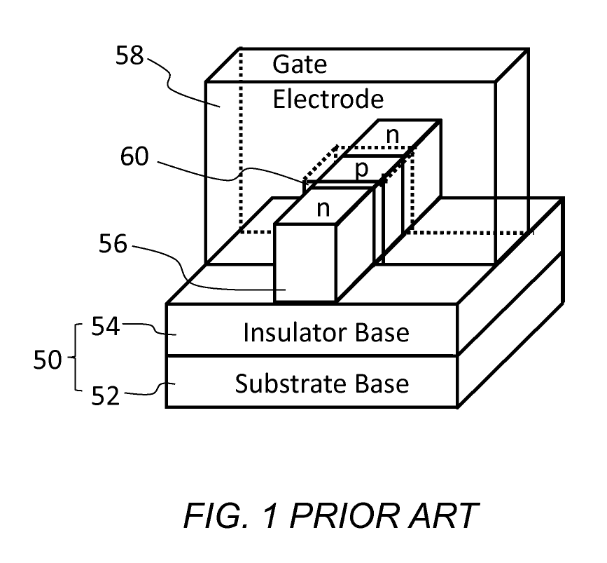

For purposes of clarity and brevity, like elements and components will bear the same designations and numbering throughout the Figures.

### DETAILED DESCRIPTION

In the Summary above and in the Detailed Description, and the claims below, and in the accompanying drawings, reference is made to particular features, including method steps, of the invention. It is to be understood that the disclosure of the invention in this specification includes all possible combinations of such particular features. For example, where a particular feature is disclosed in the context of a particular aspect or embodiment of the invention, or a particular claim, that feature can also be used, to the extent possible, in combination with and/or in the context of other particular aspects and embodiments of the invention, and in the invention generally.

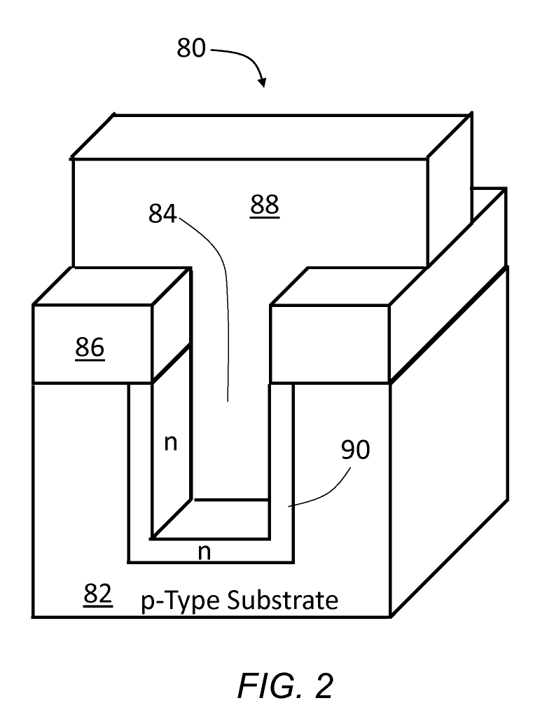

This disclosure provides a structure and fabrication method for a field effect transistor (FET) having a trough shaped channel through which electrical current flows between source and drain. An embodiment of the present invention as applied to a FET device will now be described with reference to FIG. 2. The illustrated device 80 includes a semiconductor substrate 82 of a first conductivity type having a trough structure 84 therein, the trough structure 84 extending along a first direction; an insulating layer 86 formed on top of the trough structure 84; a gate 88 formed on top of the insulating layer 86 in a second direction perpendicular to the first direction and extending over and into the trough structure 84 with a thin gate dielectric layer (not shown) interposed therebetween; a source region 90 of a second conductivity type opposite to the first conductivity type formed in the trough structure 84 on one side of the gate 88; and a drain region (not shown) of the second conductivity type formed in the trough structure 84 on other side of the gate 88.

The substrate 82 can be any semiconductor substrate known in the art, such as silicon (Si), silicon germanium (SiGe), silicon carbide (SiC), SiCGe, II-VI compounds, III-V compounds, or semiconducting epitaxial layers over such substrates. According to an embodiment of the present invention as illustrated in FIG. 2, the substrate 82 is a p-type silicon to provide a base for the formation of an n-type MOSFET device. Alternatively, the substrate 82 may be an n-type silicon to provide a base for the formation of a p-type MOSFET device according to another embodiment of the present invention.

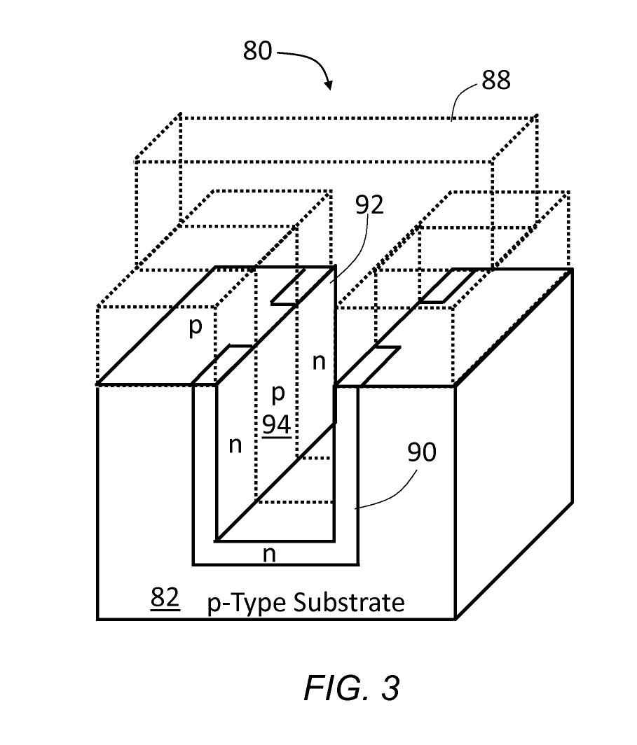

FIG. 3 is another view of the device 80 of FIG. 2 with the gate 88 and the insulating layer 86 hidden to clearly illustrate components beneath and behind the gate 88. In the drawing numerals 80 to 90 denote the same components or substances as those shown in FIG. 2. Referring now to FIG. 3, the trough structure 84 is formed in the semiconductor substrate 82 by etching. The trough structure 84 has a width of w, depth of d, and height of h while extending along its axis in the first direction. The trough structure 84 includes regions of p-type and n-type conductivities along its axis of extension. For the present embodiment as applied to an n-type MOSFET, a channel region 94 having the same p-type conductivity as the semiconductor substrate 82 is formed in the portion of the trough structure 84 adjacent to the gate 88. The channel region 94 becomes a conductive channel between the source region 90 and the drain region 92 upon application of an appropriate voltage to the gate 88. The source region 90 and the drain region 92, which bound the channel region 94 along the axis of extension, have the n-type conductivity and are formed at the two ends of the trough structure 84 divided by the gate 88. The n-type conductivity of the source region 90 and the drain region 92 can be formed by doping with any suitable dopant such as phosphorous, arsenic, or antimony. Alternatively, for another embodiment as applied to a p-type MOSFET with the n-type substrate, the channel region 94 of the trough structure 84 would have the n-type conductivity, while the source region 90 and the drain region 92 would have the p-type conductivity.

When an appropriate voltage is applied to the gate 88, the portion of the trough structure 84 adjacent to the gate 88 becomes a conductive path, or channel, through which electric current flows between the source region 90 and the drain region 92. Accordingly, the effective width of this trough channel would be 2d+w and the channel length of l is defined by the width of the gate 88. The trough cross section profile perpendicular to the extension axis thereof, as defined by the inner surface of the trough, is not limited to rectangular shapes but can also be triangular, trapezoidal, semi-circular, or semi-elliptical.

Referring now to FIG. 2, the insulating layer 86 has a sufficient thickness to prevent formation of a conductive channel on top of the trough structure 84 and may comprise any dielectric material, such as but not limited to silicon oxide (SiOₓ), silicon nitride (SiNₓ), or silicon oxynitride (SiOₓN_{y}). The insulating layer 86 may be formed by any suitable thin film deposition method, such as Physical Vapor Deposition (PVD), Chemical Vapor Deposition (CVD), or Atomic Layer Deposition (ALD).

The thin gate dielectric layer in between the gate 88 and the trough structure 84 functions like an insulating medium of a capacitor device. When a voltage is applied to the gate 88, an electric field is induced across the thin gate dielectric layer to modulate the conductance of the trough channel on the opposite side. The gate dielectric layer preferably has a thickness of between 0.5-5 nm and may comprise any material with sufficiently high dielectric constant, including but not limited to SiOₓ, SiOₓN_{y}, hafnium oxide (HfOₓ), hafnium oxynitride (HfOₓN_{y}), hafnium silicate (HfSiOₓ), HfSiOₓN_{y}, zirconium oxide (ZrOₓN_{y}), zirconium oxynitride (ZrOₓN_{y}), zirconium silicate (ZrSiOₓ), ZrSiOₓN_{y}, aluminum oxide (AlOₓ), or any combination thereof. The gate dielectric layer may be formed by thermal oxidation of the surface of the trough structure 84 or by any suitable thin film deposition method, such as CVD or ALD. In some embodiments where the substrate 82 is made of silicon, the gate dielectric layer may be made of SiOₓ formed by thermal oxidation of the trough surface. In another embodiment, the gate dielectric layer is formed of a compound comprising hafnium and oxygen, such as HfOₓ or HfSiOₓ.

With continuing reference to FIG. 2, the gate 88 forms on top of the insulating layer 86 and extends over and into the trough structure 84 along a second direction perpendicular to the first direction provided in the trough structure 84. The gate 88 supplies voltage required to modulate the conductance of the trough channel through which current flows from the source to drain. The gate 88 may comprise one or more layers of any suitable conductive material, such as doped polysilicon, tungsten silicide (WSiₓ), titanium silicide (TiSiₓ), cobalt silicide (CoSiₓ), nickel silicide (NiSiₓ), tantalum nitride (TaNₓ), titanium nitride (TiNₓ), tantalum (Ta), tungsten (W), or any combination thereof. The gate 88 may be formed by first depositing one or more layers of conductors using thin film deposition methods such as Physical Vapor Deposition (PVD), Chemical Vapor Deposition (CVD), and Atomic Layer Deposition (ALD), and followed by photo lithography and Reactive Ion Etching (RIE) to define the gate width, which also determines the channel length. In an embodiment, the gate 88 comprises doped polysilicon. In another embodiment, the gate 88 comprises at least one layer formed of TiNₓ.

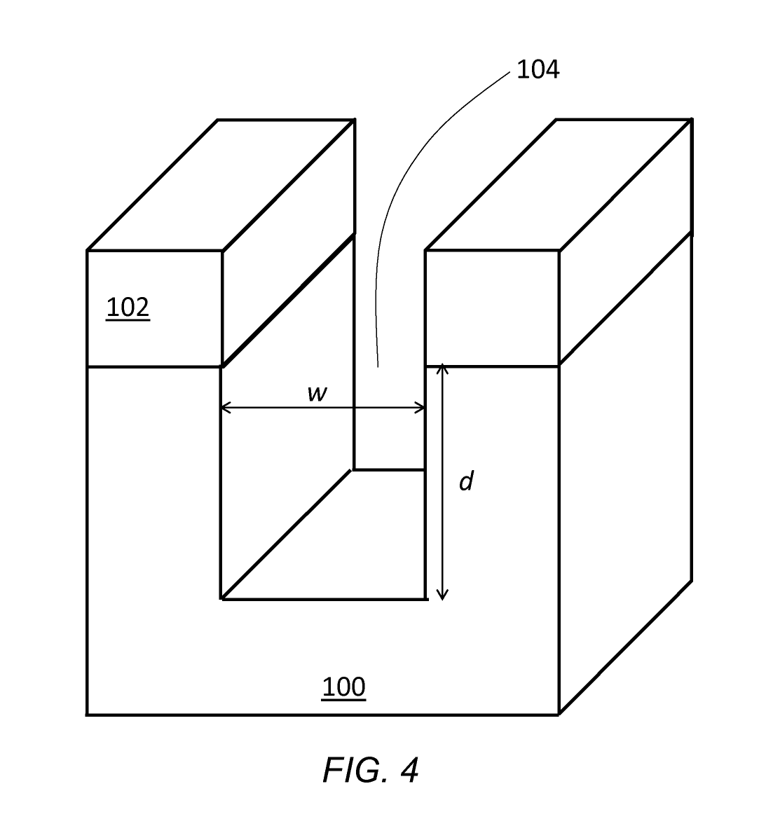

Fabrication of the trough channel transistor device 80 of FIG. 2 will now be described with reference to FIGS. 4-7, which illustrate various intermediate structures of the transistor device according to some embodiments of the present invention. Referring to FIG. 4, the processing starts by etching a semiconductor substrate 100 with an insulating layer 102 thereon to form a trough structure 104 therein. The etching mask for forming the trough structure 104 may comprise any organic resist material patterned by photo lithography, e-beam lithography, or nanoimprint lithography. The substrate 100 can be any semiconductor substrate known in the art, such as Si, SiGe, SiC, SiCGe, II-VI compounds, III-V compounds, or semiconducting epitaxial layers over such substrates. In an embodiment, the substrate 100 is made of silicon. In another embodiment, the semiconductor substrate 100 has a p-type conductivity for fabricating an n-type trough channel transistor. In still another embodiment, the semiconductor substrate 100 has an n-type conductivity for fabricating a p-type trough channel transistor. The insulating layer 102 may comprise any suitable dielectric material, including oxides, nitrides, or any combination thereof, deposited by a thin film deposition method such as PVD, CVD, or ALD. The vertical etching of the semiconductor substrate 100 and the insulating layer 102 may be carried out by a plasma etching process using suitable gas chemistries. In one embodiment where the insulating layer 102 is formed of silicon oxide, the plasma etching process of the insulating layer 102 may be carried out using a gas chemistry comprising trifluoromethane (CHF₃). In another embodiment where the substrate 100 is made of silicon, the plasma etching process of the substrate 100 may be carried out using a gas chemistry comprising hydrogen bromide (HBr) and chlorine (Cl₂).

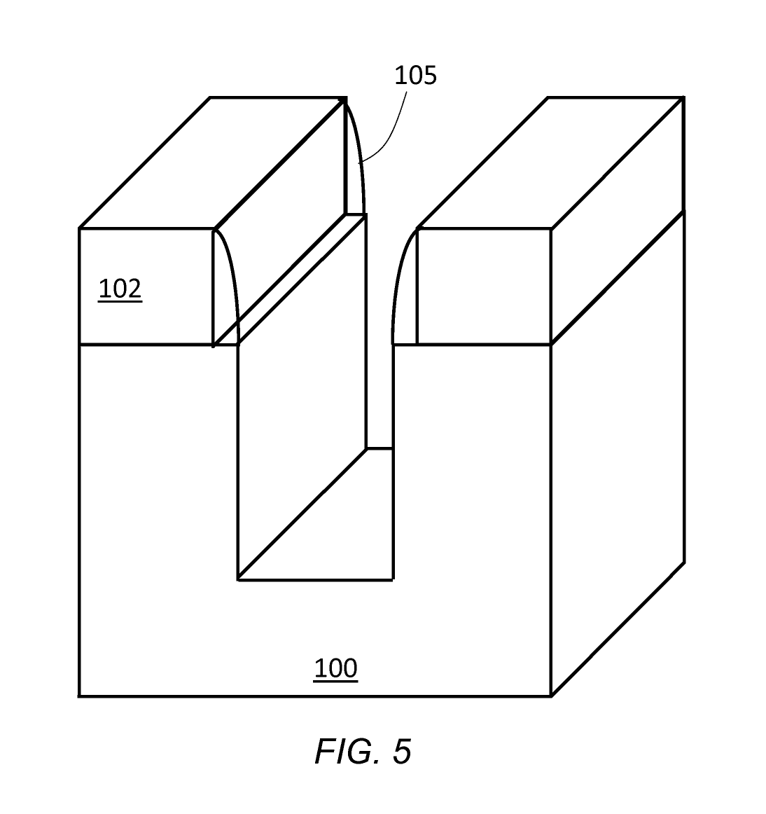

An alternative process may be used to reduce the trench width. Referring to FIG. 5, the processing starts by providing a semiconductor substrate 100 with an insulating film thereon and then removing a center portion the insulating film by a combination of photolithography and vertical dry etching to form an insulating layer 102. After the formation of the insulating layer 102, a self-aligned mask 105 is formed adjacent to the insulating layer 102 by first depositing a hard mask material and then vertically etching away the hard mask material from the top surfaces of the insulating layer 102 and the semiconductor substrate 100. The processing continues by etching a trough structure into a portion of the semiconductor substrate 100 not covered by the insulating layer 102 and the self-aligned mask 105, resulting in a structure illustrated in FIG. 5.

After the formation of the trough structure 104 in FIG. 4, the inner surface of the trough structure 104 is uniformly coated with a thin gate dielectric layer (not shown). The gate dielectric layer can be deposited by ALD or CVD and may comprise any material with sufficiently high dielectric constant, including but not limited to SiOₓ, SiOₓN_{y}, HfOₓ, HfOₓN_{y}, HfSiOₓ, HfSiOₓN_{y}, ZrOₓ, ZrOₓN_{y}, ZrSiOₓ, ZrSiOₓN_{y}, AlOₓ, or combinations thereof. In embodiments where the semiconductor substrate 100 is made of silicon, the gate dielectric layer may be formed of silicon oxide by thermal oxidation of the trough surface.

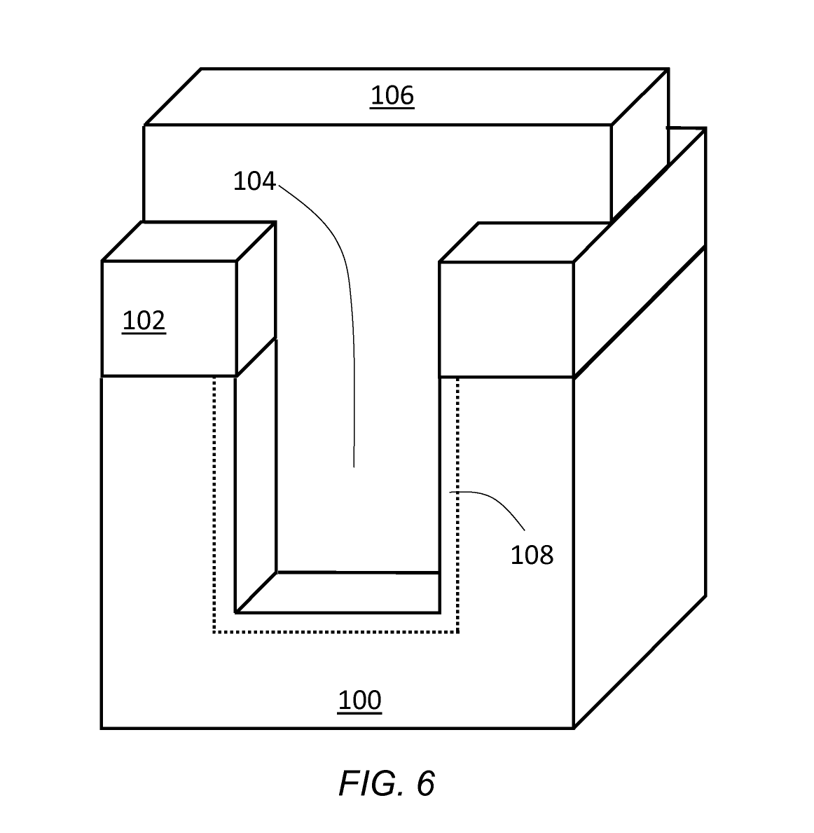

After the deposition of the gate dielectric layer, a conductive material is deposited and fills the trough structure 104, following by planarization with chemical mechanical polishing (CMP). The planarized conductive material is then patterned by the combined processes of lithography and vertical dry etching to form a gate 106 on top of the insulating layer 102 in the second direction and extending over and into the trough structure 104 with the gate dielectric layer interposed therebetween, as illustrated in FIG. 6, in a manner as well known to one of skill in the art.

With continuing reference to FIG. 6, ion implantation of the trough structure 104 to define source and drain follows the formation of the gate 106. The gate 106 serves as an implantation mask to preserve the conductivity type of the region of the trough structure 104 beneath the gate 106. In regions of the trough structure 104 not covered by the gate 106, low dose of dopant is implanted into the trough wall and bottom by angled ion implantation to form a lightly doped drain (LDD) structure 108 in such a way that these regions have a different conductivity type compared with the substrate 100 and the trough region beneath the gate 106. The ion implantation is tilted in the first direction (i.e. the trough extension direction) to create overlap under the gate 106 and in the second direction (i.e. gate extension direction) to form a LDD layer in the sidewalls of the trough structure 104. In some embodiments where an n-type trough channel transistor is fabricated, implanted dopant may comprise any Group III element, including boron, aluminum, indium, or gallium. In alternative embodiments where a p-type trough channel transistor is fabricated, implanted dopant may comprise any Group V element, such as phosphorous, arsenic, or antimony.

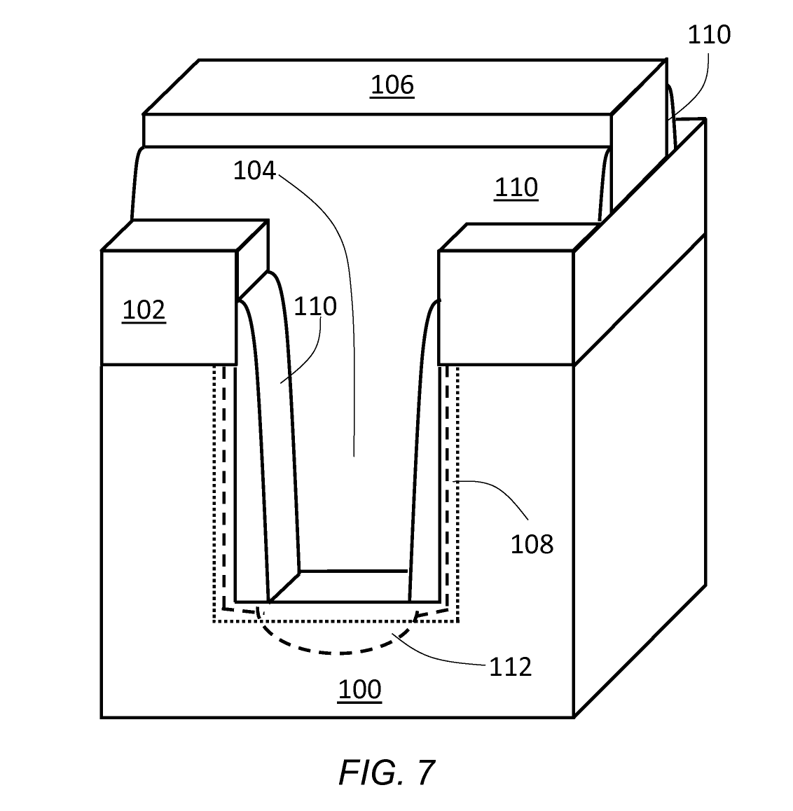

After ion implantation to define the source and drain regions, the processing of the trough channel transistor may continue by depositing a conformal dielectric layer and then vertically etching the same layer to form an insulating spacer layer 110 on the sidewalls of the gate 106 and the trough structure 104 as illustrated in FIG. 7. The conformal dielectric layer is preferably made of a material having a low etch rate in the silicon oxide etching chemistry, such as silicon nitride for self-aligned contact (SAC) process.

With continuing reference to FIG. 7, a second, higher dose of dopant is implanted into the bottom of the trough structure 104 on both sides of the gate 106 to form the source region 112 and the drain region (behind the gate in the figure). The second ion implantation is tilted in the second direction to pass dopant atoms through the spacer layer 110 to form an n+ or p+ layer on the sidewalls of the trough structure 104. Unlike the first ion implantation, the second ion implantation is not tilted in the first direction in order to prevent the formation of n+ or p+ region directly beneath the gate 106. In some embodiments where an n-type trough channel transistor is fabricated, implanted dopant may comprise any Group III element, including boron, aluminum, indium, or gallium. In alternative embodiments where a p-type trough channel transistor is fabricated, implanted dopant may comprise any Group V element, such as phosphorous, arsenic, or antimony.

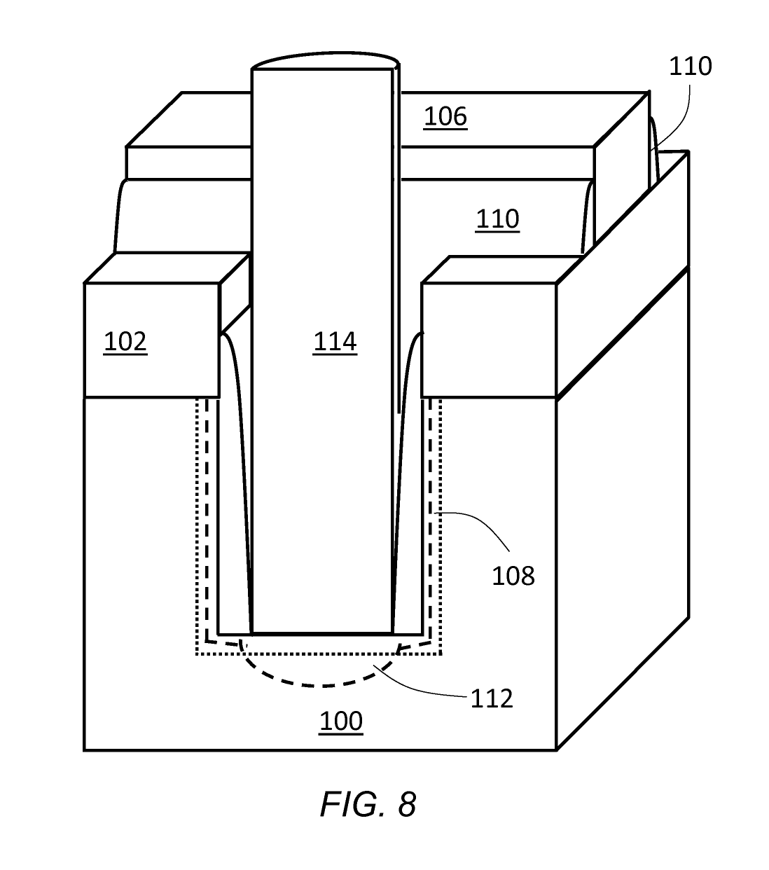

Referring to FIG. 8, a contact stud 114 may be formed on the source region 112 and the drain region (behind the gate in the figure) using a conventional SAC process in a manner as well known to one of skill in the art. After the formation of the contact stud 114, the processing may continue with back end of line (BEOL) processes.

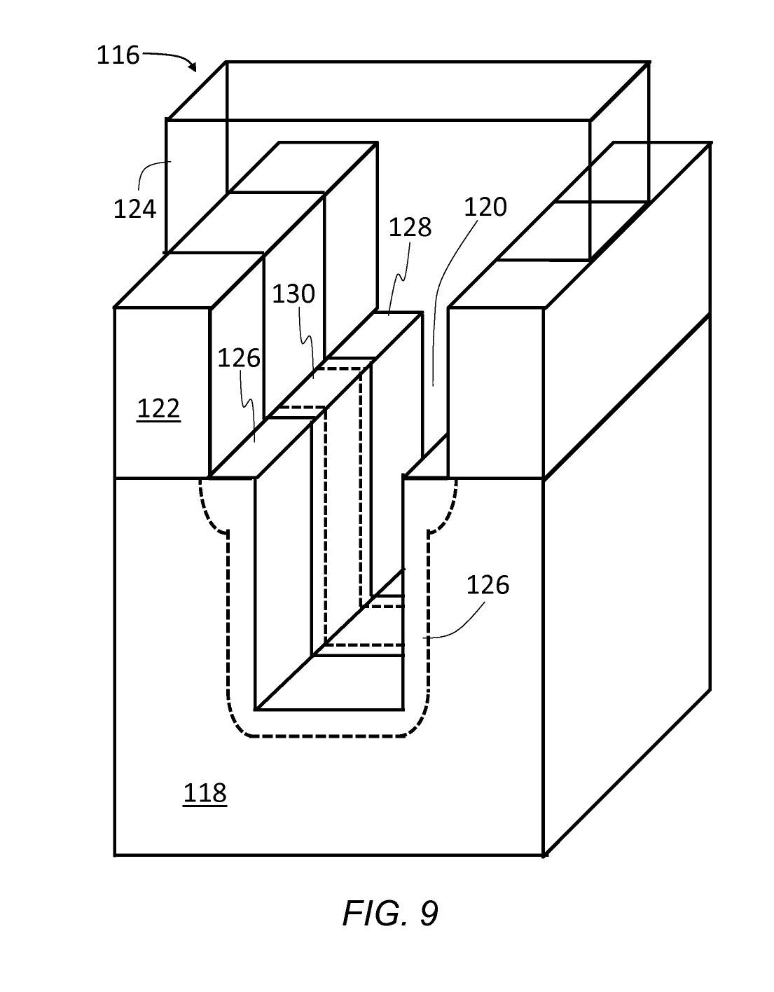

Another embodiment of the present invention as applied to a FET device will now be described with reference to FIG. 9. The illustrated device 116 includes a semiconductor substrate 118 of a first conductivity type having a trough structure 120 therein with the trough structure 120 extending along a first direction; an insulating layer 122 partially covering top of the trough structure 120 to form two ledges on top of the trough structure 120; a gate 124 formed on top of the insulating layer 122 and the trough structure 120 in a second direction perpendicular to the first direction and extending over and into the trough structure 120 with a thin gate dielectric layer (not shown) interposed therebetween; a source region 126 of a second conductivity type opposite to the first conductivity type formed in the trough structure 120 on one side of the gate 124; and a drain region 128 of the second conductivity type formed in the trough structure 120 on other side of the gate 124. The gate 124 is made transparent in the figure to illustrate components beneath and behind the gate 124.

The MOSFET device 116 of FIG. 9 is different from the MOSFET device 80 of FIG. 2 in that the trough structure 120 has two ledges on top, thereby effectively increasing the channel width for a given trough height and width. The trough structure 120 is formed in the semiconductor substrate 118 by etching and has a width of w, depth of d, and height of h while extending along its axis in the first direction. The trough structure 120 includes regions of p-type and n-type conductivities along its axis of extension. For an n-type MOSFET device, a channel region 130 having the same p-type conductivity as the semiconductor substrate 118 is formed in the portion of the trough structure 120 adjacent to the gate 124. The channel region 130 becomes a conductive path between the source region 126 and the drain region 128 upon application of an appropriate voltage to the gate 124. The source region 126 and the drain region 128, which bound the channel region 130 along the axis of extension, have the n-type conductivity and are formed at the two ends of the trough structure 120 divided by the gate 124. The n-type conductivity of the source region 126 and the drain region 128 for the n-type MOSFET device can be formed by doping with any suitable dopant such as phosphorous, arsenic, or antimony. Alternatively, for another embodiment as applied to a p-type MOSFET with the n-type substrate, the channel region 130 of the trough structure 84 would have the n-type conductivity, while the source region 126 and the drain region 128 would have the p-type conductivity.

When an appropriate voltage is applied to the gate 124, the channel region 130 becomes a conductive path, or channel, through which electric current flows between the source region 126 and the drain region 128. The trough cross section profile perpendicular to the extension axis thereof, as defined by the inner surface of the trough, is not limited to rectangular shapes but can also be triangular, trapezoidal, semi-circular, or semi-elliptical.

With continuing reference to FIG. 9, the insulating layer 122 has a sufficient thickness to prevent formation of a conductive channel therebeneath and may comprise any dielectric material, such as but not limited to silicon oxide (SiOₓ), silicon nitride (SiNₓ), or silicon oxynitride (SiOₓN_{y}). The insulating layer 122 may be formed by any suitable thin film deposition method, such as Physical Vapor Deposition (PVD), Chemical Vapor Deposition (CVD), or Atomic Layer Deposition (ALD).

The thin gate dielectric layer in between the gate 124 and the trough structure 120 functions like an insulating medium of a capacitor device. When a voltage is applied to the gate 124, an electric field is induced across the thin gate dielectric layer to modulate the conductance of the trough channel on the opposite side. The gate dielectric layer preferably has a thickness of between 0.5-5 nm and may comprise any material with sufficiently high dielectric constant, including but not limited to SiOₓ, SiOₓN_{y}, hafnium oxide (HfOₓ), hafnium oxynitride (HfOₓN_{y}), hafnium silicate (HfSiOₓ), HfSiOₓN_{y}, zirconium oxide (ZrOₓ), zirconium oxynitride (ZrOₓN_{y}), zirconium silicate (ZrSiOₓ), ZrSiOₓN_{y}, aluminum oxide (AlOₓ), or any combination thereof. The gate dielectric layer may be formed by thermal oxidation of the surface of the trough structure 120 or by any suitable thin film deposition method, such as CVD or ALD. In some embodiments where the substrate 118 and the trough structure 120 are made of silicon, the gate dielectric layer may be made of SiOₓ formed by thermal oxidation of the trough surface. In another embodiment, the gate dielectric layer is formed of a compound comprising hafnium and oxygen, such as HfOₓ or HfSiOₓ.

With continuing reference to FIG. 9, the gate 124 forms on top of the insulating layer 122 and extends over and into the trough structure 120 along a second direction perpendicular to the first direction provided in the trough structure 120. The gate 124 supplies voltage required to modulate the conductance of the trough channel through which current flows from the source to drain. The gate 124 may comprise one or more layers of any suitable conductive material, such as doped polysilicon, tungsten silicide (WSiₓ), titanium silicide (TiSiₓ), cobalt silicide (CoSiₓ), nickel silicide (NiSiₓ), tantalum nitride (TaNₓ), titanium nitride (TiNₓ), tantalum (Ta), tungsten (W), or combinations thereof. The gate 124 may be formed by first depositing one or more layers of conductors using thin film deposition methods such as Physical Vapor Deposition (PVD), Chemical Vapor Deposition (CVD), and Atomic Layer Deposition (ALD), and followed by photo lithography and Reactive Ion Etching (RIE) to define the gate width, which also determines the channel length. In an embodiment, the gate 124 comprises doped polysilicon. In another embodiment, the gate 124 comprises at least one layer formed of TiNₓ.

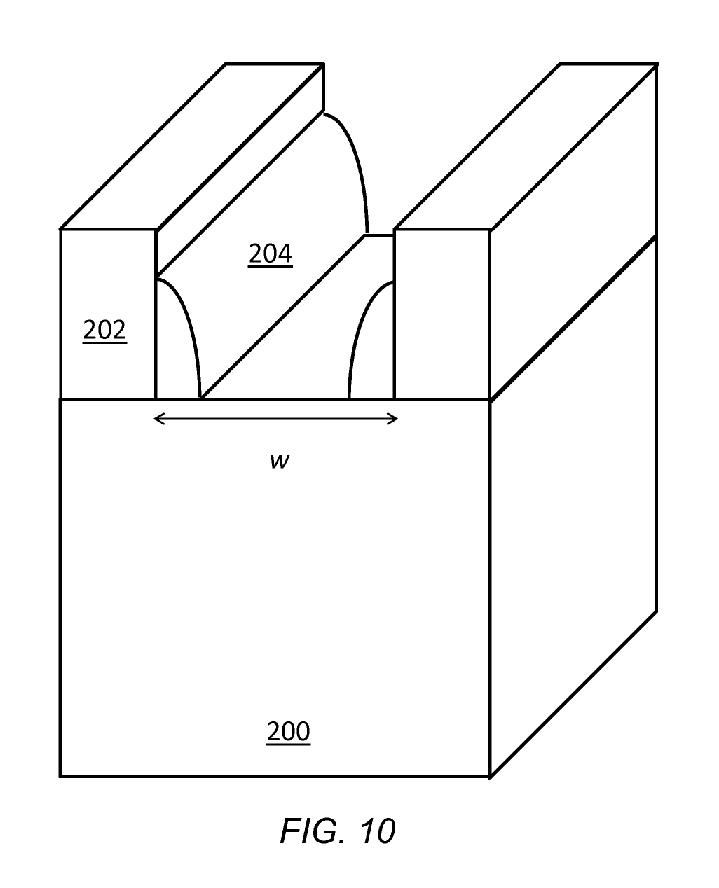

Fabrication of the trough channel transistor device 116 of FIG. 9 will now be described with reference to FIGS. 10-15, which illustrate various intermediate structures of the transistor device 116 according to some embodiments of the present invention. Referring to FIG. 10, the processing starts by providing a semiconductor substrate 200 with an insulating film thereon and then removing a center portion the insulating film by a combination of photolithography and vertical dry etching to form an insulating layer 202. After the formation of the insulating layer 202, a self-aligned mask 204 is formed adjacent to the insulating layer 202 by first depositing a hard mask material and then vertically etching away the hard mask material from the top surfaces of the insulating layer 202 and the semiconductor substrate 200. The substrate 200 can be any semiconductor substrate known in the art, such as Si, SiGe, SiC, SiCGe, II-VI compounds, III-V compounds, or semiconducting epitaxial layers over such substrates. In an embodiment, the substrate 200 is made of silicon. In another embodiment, the semiconductor substrate 200 has a p-type conductivity for fabricating an n-type trough channel transistor. In still another embodiment, the semiconductor substrate 200 has an n-type conductivity for fabricating a p-type trough channel transistor. The insulating layer 202 may comprise any suitable dielectric material, including oxides, nitrides, or any combination thereof, deposited by a thin film deposition method such as PVD, CVD, or ALD. The vertical etching of the insulating layer 202 may be carried out by a plasma etching process using suitable gas chemistries. In one embodiment where the insulating layer 202 is formed of silicon oxide, the plasma etching process of the insulating layer 202 may be carried out using a gas chemistry comprising trifluoromethane (CHF₃).

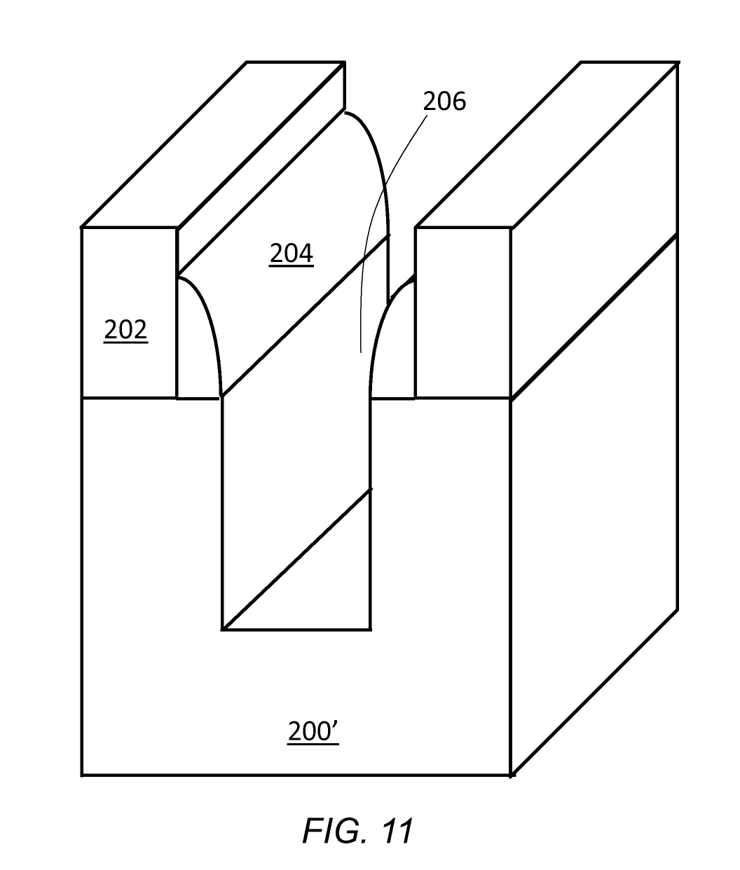

The processing continues by etching a trough structure 206 into a portion of the semiconductor substrate 206 not covered by the insulating layer 202 and the self-aligned mask 204, resulting in a structure illustrated in FIG. 11. In some embodiments where the substrate 200 is made of silicon, the plasma etching process of the substrate 200 may be carried out using a gas chemistry comprising hydrogen bromide (HBr) and chlorine (Cl₂).

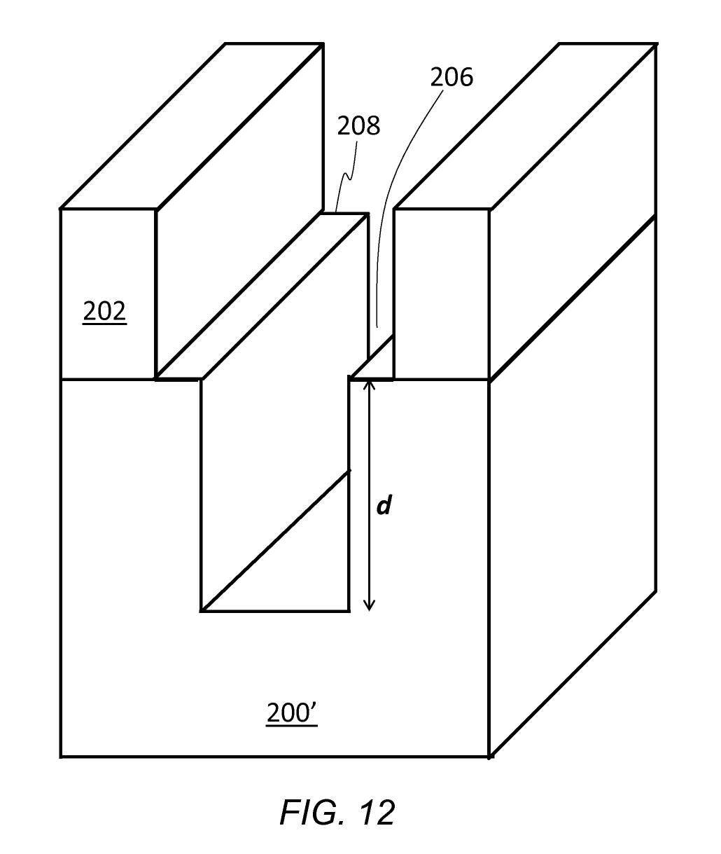

Referring to FIG. 12, after formation of the trough structure 206 in the substrate 200′, the self-aligned mask 204 is removed, thereby partially exposing top of the trough structure 206 to form two ledges 208. In some embodiments where the self-aligned mask 204 is made of silicon nitride, the self-aligned mask 204 may be removed by wet etch with hot phosphoric acid.

After the formation of the trough structure 206, the ledges 208 and the inner surface of the trough structure 206 is uniformly coated with a thin gate dielectric layer (not shown). The gate dielectric layer can be deposited by ALD or CVD and may comprise any material with sufficiently high dielectric constant, including but not limited to SiOₓ, SiOₓN_{y}, HfOₓ, HfOₓN_{y}, HfSiOₓ, HfSiOₓN_{y}, ZrOₓ, ZrOₓN_{y}, ZrSiOₓ, ZrSiOₓN_{y}, AlOₓ, or combinations thereof. In embodiments where the trough structure 206 is made of silicon, the gate dielectric layer may be formed of silicon oxide by thermal oxidation of the trough surface.

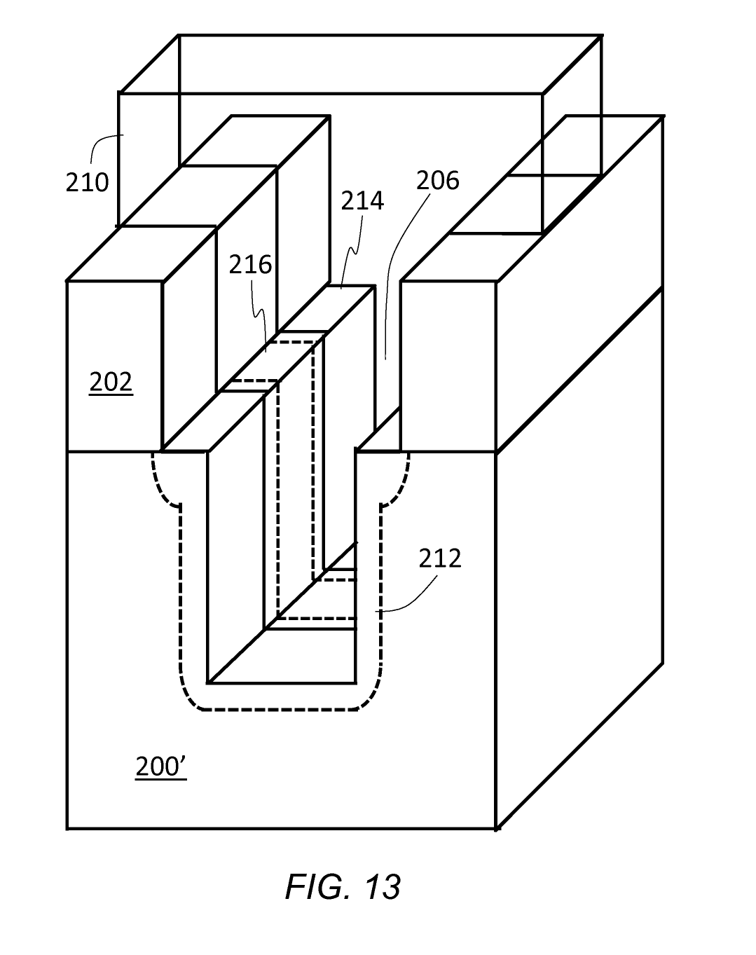

After the deposition of the gate dielectric layer, a conductive material is deposited and fills the trough structure 206, following by planarization with chemical mechanical polishing (CMP). The planarized conductive material is then patterned by the combined processes of lithography and vertical dry etching to form a gate 210 on top of the insulating layer 202 in the second direction and extending over and into the ledges 208 and the trough structure 206 with a gate dielectric layer interposed therebetween, as illustrated in FIG. 13, in a manner as well known to one of skill in the art. The gate 210 is made transparent in FIG. 13 in order to clearly show other components beneath and behind the gate 210.

With continuing reference to FIG. 13, ion implantation of the trough structure 206 to define source and drain follows the formation of the gate 210. The gate 210 serves as an implantation mask to preserve the conductivity type of the region of the trough structure 206 beneath the gate 210. In regions 212 and 214 of the trough structure 206 not covered by the gate 210, low dose of dopant is implanted into the trough wall, bottom, and ledges by angled ion implantation to form a lightly doped drain (LDD) structure in such a way that these regions 212 and 214 have an opposite conductivity type compared with the substrate 200′ and the trough region beneath the gate 210. The trough region beneath the gate 210 defines a channel region 216 bounded between the LDD regions 212 and 214. The ion implantation is tilted in the first direction (i.e. the trough extension direction) to create overlap under the gate 210 and in the second direction (i.e. gate extension direction) to form a LDD layer in the sidewalls of the trough structure 206. In some embodiments where an n-type trough channel transistor is fabricated, implanted dopant may comprise any Group III element, including boron, aluminum, indium, or gallium. In alternative embodiments where a p-type trough channel transistor is fabricated, implanted dopant may comprise any Group V element, such as phosphorous, arsenic, or antimony.

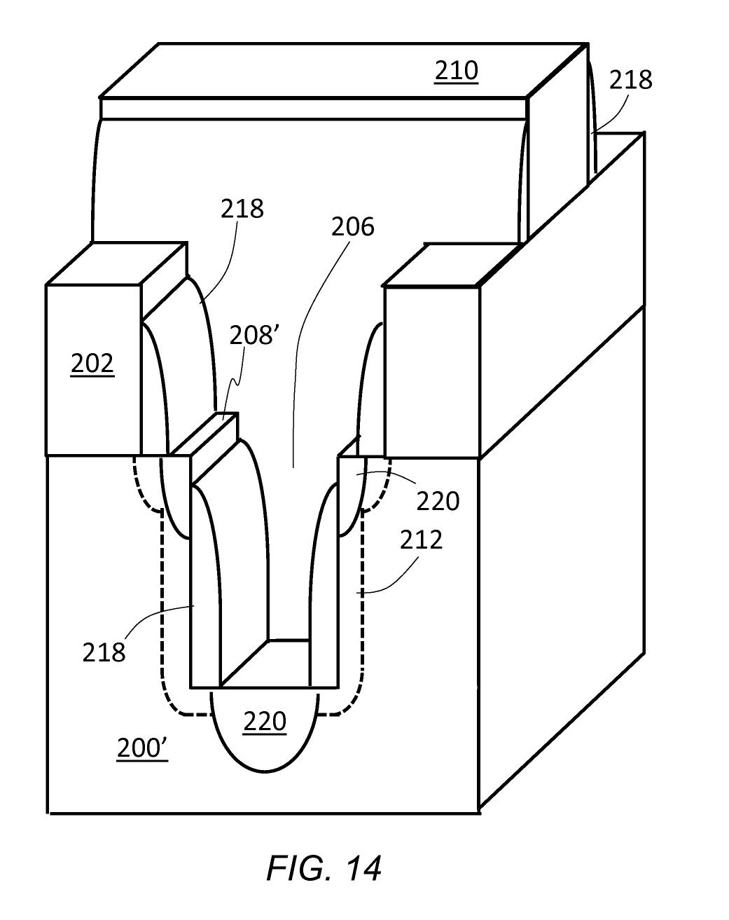

After ion implantation to define the LDD regions 212 and 214, the processing of the trough channel transistor may continue by depositing a conformal dielectric layer and then vertically etching the same layer to form an insulating spacer layer 218 on the sidewalls of the gate 210, the trough structure 206, and the insulating layer 202 as illustrated in FIG. 14. The dielectric layer is preferably made of a material having a low etch rate in the silicon oxide etching chemistry, such as silicon nitride for self-aligned contact (SAC) process.

With continuing reference to FIG. 14, a second, higher dose of dopant for forming n+ or p+ region is implanted into the ledges 208′ and the trough structure 206 on both sides of the gate 210 to form of n+ or p+ region 220 not covered by the insulating spacer layer 218, effectively creating a source 220 and a drain (not shown) on both sides of the gate 210. The second ion implantation is tilted in the second direction to pass dopant atoms through the spacer layer 218 to form an n+ or p+ layer on the sidewalls of the trough structure 206. Unlike the first ion implantation, the second ion implantation is not tilted in the first direction in order to prevent the formation of n+ or p+ regions directly beneath the gate 210. In some embodiments where an n-type trough channel transistor is fabricated, implanted dopant may comprise any Group III element, including boron, aluminum, indium, or gallium. In alternative embodiments where a p-type trough channel transistor is fabricated, implanted dopant may comprise any Group V element, such as phosphorous, arsenic, or antimony.

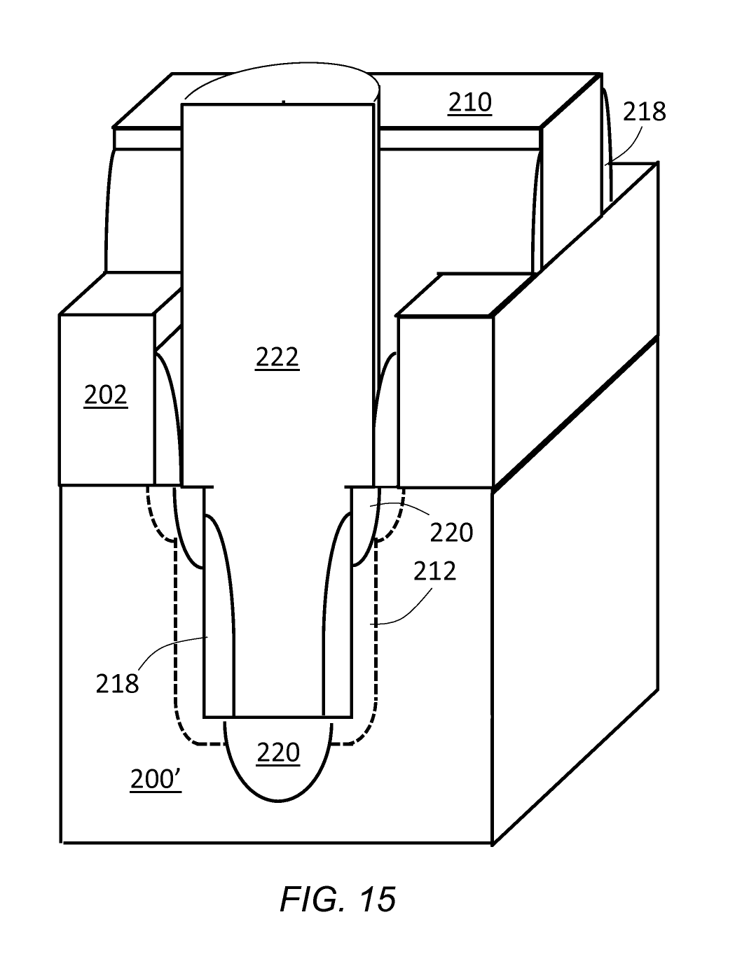

Referring to FIG. 15, a contact stud 222 may be formed on the source 220 and the drain (behind the gate in the figure) using a conventional SAC process in a manner as well known to one of skill in the art. After the formation of the contact stud 114, the processing may continue with back end of line (BEOL) processes.

The previously described embodiments of the present invention have many advantages, including cost-saving from not having to use expensive SOI substrates and ability to apply substrate bias. It is important to note, however, that the invention does not require that all the advantageous features and all the advantages need to be incorporated into every embodiment of the present invention. All the features disclosed in this specification, including any accompanying claims, abstract, and drawings, may be replaced by alternative features serving the same, equivalent or similar purpose, unless expressly stated otherwise. Thus, unless expressly stated otherwise, each feature disclosed is one example only of a generic series of equivalent or similar features.

While the present invention has been shown and described with reference to certain preferred embodiments, it is to be understood that those skilled in the art will no doubt devise certain alterations and modifications thereto which nevertheless include the true spirit and scope of the present invention. Thus the scope of the invention should be determined by the appended claims and their legal equivalents, rather than by examples given.

Any element in a claim that does not explicitly state “means for” performing a specified function, or “step for” performing a specific function, is not to be interpreted as a “means” or “step” clause as specified in 35 U.S.C. §112, ¶ 6. In particular, the use of “step of” in the claims herein is not intended to invoke the provisions of 35 U.S.C. §112, ¶ 6.

What is claimed is:

1. A field effect transistor device comprising:
a semiconductor substrate of a first conductivity type having a trough structure therein, said trough structure extending along a first direction;
an insulating layer formed on top of said trough structure;
a gate formed on top of said insulator layer in a second direction perpendicular to said first direction and extending over and into said trough structure with a gate dielectric layer interposed therebetween;
a source of a second conductivity type opposite to said first conductivity type formed in said trough structure on one side of said gate; and
a drain of said second conductivity type formed in said trough structure on other side of said gate.

2. The transistor device according to claim 1, further comprising a channel of said first conductivity type between said source and drain in said trough structure.

3. The transistor device according to claim 1, further comprising a contact stud formed on top of each of said source and drain.

4. The transistor device according to claim 1, wherein said first conductivity type is p type and said second conductivity type is n type.

5. The transistor device according to claim 1, wherein said first conductivity type is n type and said second conductivity type is p type.

6. The transistor device according to claim 1, wherein said semiconductor substrate comprises silicon.

7. The transistor device according to claim 1, wherein said gate dielectric layer comprises silicon oxide.

8. The transistor device according to claim 1, wherein said gate dielectric layer is formed of a compound comprising hafnium and oxygen

9. The transistor device according to claim 1, wherein said gate electrode comprises doped polysilicon.

10. The transistor device according to claim 1, wherein said gate includes at least one layer formed of titanium nitride.

11. The transistor device according to claim 1, wherein said insulating layer is formed of silicon oxide, silicon nitride, or silicon oxynitride.

12. The transistor device according to claim 1, wherein said insulating layer partially covers top of said trough structure to form two ledges on top of said trough structure.

13. A method for manufacturing the transistor device of claim 1, the method comprising the steps of:
providing a semiconductor substrate having a first type conductivity;
depositing an insulating layer on top of said semiconductor substrate;
forming a trough structure in said semiconductor substrate;
forming a gate dielectric layer on the surface of said trough structure;
forming a gate on top of said insulating layer, said gate extending over and into said trough structure with said gate dielectric layer interposed therebetween; and
forming a source and a drain having a second conductivity type opposite to said first conductivity type in said trough structure by ion implantation using said gate as a mask.

14. The method according to claim 13, wherein said first conductivity type is p type and said second conductivity type is n type.

15. The method according to claim 13, wherein said first conductivity type is n type and said second conductivity type is p type.

16. The method according to claim 13, wherein said semiconductor substrate is formed of silicon and said gate dielectric layer is formed of silicon oxide.

17. The method according to claim 16, wherein the step of forming said gate dielectric layer is carried out by thermal oxidation of said trough structure.

18. A field effect transistor device comprising:
a p-type silicon substrate having a trough structure therein, said trough structure extending along a first direction;
an insulating layer formed on top of said trough structure;
a gate made of doped polysilicon formed on top of said insulator layer in a second direction perpendicular to said first direction and extending over and into said trough structure with a gate oxide layer interposed therebetween;
a source having an n-type conductivity formed in said trough structure on one side of said gate; and
a drain having said n-type conductivity formed in said trough structure on other side of said gate.

19. The transistor device according to claim 18, further comprising a channel having said p-type conductivity between said source and drain in said trough structure.

20. The transistor device according to claim 18, further comprising a contact stud formed on top of each of said source and drain.
